(19) United States
(12) Patent Application Publication
(10) Pub. No.: US 2006/0284218 A1
(43) Pub. Date: Dec. 21, 2006

(54) Nanoelectonic devices based on nanowire networks

(75) Inventors: Richard B. Kaner, Pacific Palisades, CA (US); Jiaxing Huang, Los Angeles, CA (US); George Gruner, Los Angeles, CA (US)

Correspondence Address: VENABLE LLP, P.O. BOX 34385, WASHINGTON, DC, 20043-9998, US

(73) Assignee: THE REGENTS OF THE UNIVERSITY OF CALIFORNIA, Oakland, CA (US)

(21) Appl. No.: 10/570,277

(22) PCT Filed: Sep. 1, 2004
(86) PCT No.: PCT/US04/28633

§ 371 Date: Mar. 2, 2006

Related U.S. Application Data
(60) Provisional application No. 60/500,077, filed on Sep. 3, 2003.

(51) Int. Cl. H01L 29/76

(52) U.S. Cl. 257/288; 257/E51.04; 977/938

(57) ABSTRACT

Semiconductor devices where networks of molecular nanowires (or nanofibers) are used as the semiconductor material. Field effect transistors are disclosed where networks of molecular nanowires are used to provide the electrical connection between the source and drain electrodes. The molecular nanowires have diameters of less than 500 nm and aspect ratios of at least 10. The molecular nanowires that are used to form the networks can be single element nanowires, Group III-V nanowires, Group II-VI nanowires, metal oxide nanowires, metal chalcogenide nanowires, ternary chalcogenide nanowires and conducting polymer nanowires.

### BACKGROUND OF THE INVENTION

1. Field of the Invention

The present invention relates generally to semiconductor devices and the materials that are used as the semiconductor elements in such devices. More particularly, the invention is directed to the use of networks of molecular nanowires as the semiconductor element in such devices.

2. Description of Related Art

The publications and other reference materials referred to herein to describe the background of the invention and to provide additional detail regarding its practice are hereby incorporated by reference. For convenience, the reference materials are numerically referenced and grouped in the appended bibliography.

Nanoscale electronic devices that include components other that silicon offer attractive alternatives to traditional devices made using photolithographic methods. Various wires, with dimensions less that one micron have been fabricated or grown and some of them have been demonstrated to function as active electronic devices and have been used as components of electronic devices.

For example, devices have been made which include Si and related nanowires and other semiconducting nanowires including those made from Group III-V or Group II-VI compounds (59). Transistor operation using individual nanowires has been demonstrated. However, fabrication of such devices, where a single nanowire connects the (source and drain) electrodes, are technically demanding, particularly at small dimensions.

Electronic devices that utilize carbon nanotubes have been demonstrated as possible replacements for fabricated devices (201). Diode, transistor and logic element operation has been demonstrated. Such devices are grown using high temperature conditions, and contain a mixture of semiconducting and metallic nanotubes.

Networks of nanotubes have also been shown to support Field Effect Transistor (FET) operation (202). However, doping and thus the tailoring of the conductivity of individual tubes is difficult. Accordingly, the optimization of device parameters is hampered.

In view of the above, there is a need for devices with the nanoscale conducting channels different from fabricated nanowires or nanotubes.

### SUMMARY OF THE INVENTION

In accordance with the present invention, nanoelectronic semiconductor devices are provided where networks of molecular nanowires (or nanofibers) are used in place of the conventional semiconductor materials that are present in such devices. In a particular embodiment, field effect transistors are provided where networks of molecular nanowires are used to provide the electrical connection between the source electrode and drain electrode. The present invention not only covers the nanoelectronic devices themselves and the electronic devices they are used in, but also covers methods for making the nanoelectronic devices and methods for controlling the flow of electrical current between source and drain electrodes when networks of molecular nanowires are used as the semiconductor connection between the electrodes.

As a feature of the present invention, the molecular nanowires used to form the semiconductor networks have diameters of less than 500 nm and aspect ratios of at least 10. As another feature, the molecular nanowires that are used to form the networks can be single element nanowires, Group III-V nanowires, Group II-VI nanowires, metal oxide nanowires, metal chalcogenide nanowires, ternary chalcogenide nanowires and conducting polymer nanowires.

The present invention is applicable to a wide variety of electronic devices where networks of molecular nanowires (or nanofibers) can be used as conducting channels to satisfy the need for devices with the nanoscale conducting channels different from fabricated nanowires or nanotubes that was described above. Doped nanowires and/or nanofibers) also form part of the present invention. Furthermore, the molecular networks of nanowires in accordance with the present invention can be used in the fabrication of electronic devices, such as chemical or biosensors and as conducting elements for both passive and active electronic devices including resistors, diodes, transistors and logic elements.

The above discussed and many other features and attendant advantages of the present invention will become better understood by reference to the detailed description when taken in conjunction with the accompanying drawings.

### BRIEF DESCRIPTION OF THE DRAWINGS

FIG. 1 is a schematic representation of a nanowire or nanofiber network based electronic device. In addition to a source (S) and drain (D), a gate (G) voltage can also be applied, in a usual transistor configuration, leading to a three terminal device.

FIG. 2 is a scanning electron microscopy image showing a polyaniline nanofiber network on a field effect transistor (FET) device. The average diameter of the nanofibers is 50 nm.

FIG. 3 is a graph showing the dependence of the source-drain current I_{sd} on the gate voltage V_{g}. The dependence indicated p-type polyaniline doping. The hysteresis is common for liquid-gated devices. The dependence of the source-drain current on doping is due to the increasing conductance of the network.

FIG. 4 is a graph showing source-drain current (I_{sd}) versus source-drain voltage (V_{sd}). The linear behavior indicates that the current is determined by the polyaniline network. The dependence of the slope on the gate voltage V_{g} shows the transistor operation of the device.

FIG. 5 is a diagrammatic representation of the formation of nanowire networks in accordance with the present invention using chemical vapor deposition (CVD).

### DETAILED DESCRIPTION OF THE INVENTION

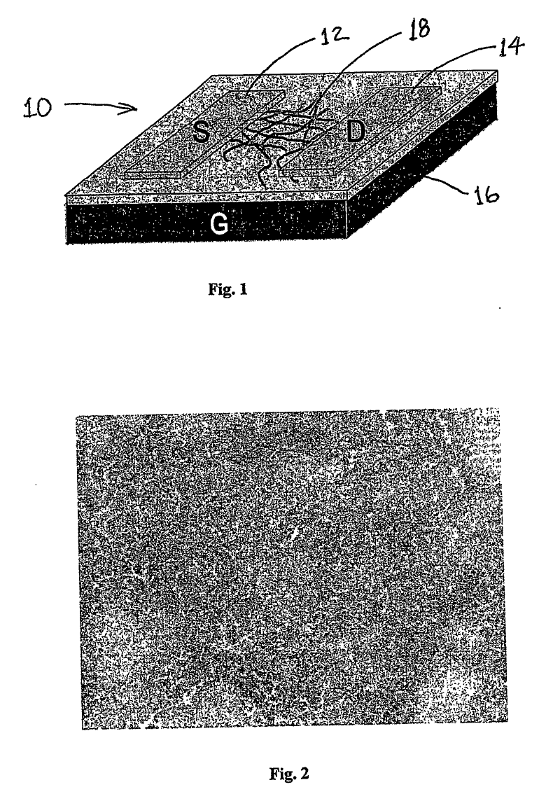

An exemplary field effect transistor (FET) that utilizes a network of molecular nanowires (or nanofibers) in accordance with the present invention is shown generally in FIG. 1 at 10. The FET 10 includes a source electrode (S) 12, a drain electrode (D) 14 and a gate electrode (G) 16. The network of molecular nanowires is shown at 18. As is typical in any FET, an electrically insulating layer 20 is provided between the gate electrode and the semiconductor material (nanowire network 18). The insulating layer can be silicon dioxide (see Ref. 202), non-conducting polymer, such as epoxy. The electrodes can be made from any of the materials used in conventional FET devices. The FET operates in the same manner as conventional FET's except that that typical semiconductor material that is present between the source and drain electrodes is replaced with a network of molecular nanowires.

For the purposes of this specification, molecular nanowires are defined as having dimensions less than 500 nm in diameter (the diameter is the average of the cross-sectional width) and have an aspect ratio exceeding 10 (e.g. a 100 nm diameter nanowire must have a length that is equal to or greater than 1 micron). The term “molecular nanowire” is used herein interchangeably with “molecular nanofibers” and it is intended that when the term “molecular nanowire” is used alone, it includes molecular nanofibers.

The network of molecular nanofibers 18 can be made from a variety of known molecular semiconductor nanowires. Set forth below is a listing of known exemplary molecular nanowire materials that can be used to make networks of molecular nanowires in accordance with the present invention.

Single element nanowires made from silicon using known procedures may be used to form the network 18. The procedures for making such nanowires are set forth in detail in Refs. 1-21. Single element nanowires made from germanium may also be used. Details of synthesis are set forth in Refs. 9, 17 and 22-27. Other exemplary single element nanowires include selenium and tellurium nanowires, which are made according to known procedures as set forth in Refs. 28-29 and Ref. 30, respectively.

Nanowires made from a combination of Group III-V materials using known procedures may be used to form the network 18. Exemplary Group III-V materials that can be used to form nanowire networks include Ga, In, N, P, As and Sb. Details of exemplary synthesis procedures for these nanowires are set forth as follows: GaN (Refs. 8, 31-45); GaP (Refs. 39, 46 and 47); GaAs (Refs. 42 and 48-50); InN (Ref. 51); InP (Refs. 8, 38 and 52-54); and InAs (Ref. 55).

Nanowires made from a combination of Group II-VI materials using known procedures may also be used to form the network 18. Exemplary group II-VI materials that can be used to form nanowire networks include Zn, Cd, Hg, S, Se and Te. Details of exemplary synthesis procedures for these nanowires are set forth as follows: ZnS (Refs. 56-60); ZnSe (Refs. 44, 59 and 60); CdS (Refs. 59-72); CdSe (Refs. 59, 60, 65, 68, 69, 71 and 73); CdTe (Refs. 65, 73 and 74); and HgS (Ref. 75).

Nanowires made from metal oxides using known procedures may be used to form the network 18. Exemplary metal oxide nanowires and references to the details for making them are as follows; CdO (Refs. 76-78); Ga₂O₃ (Refs. 79-88); In₂O₃ (Refs. 85 and 89-99); MnO (Refs. 100-102); NiO (Ref. 103); PbO (Ref. 104); Sb₂O₃ (Ref. 25); SnO₂ (94 and 105-112); and ZnO (Refs. 113-117).

Nanowires made from metal chalcogenides using known procedure may be used to form the network 18. Exemplary metal chalcogenides that can be used to make nanowires include Mn, Fe, Co, Ni, Cu, Ag, Sn, Pb and Bi. Exemplary metal chalcogenide nanowires and references to the details for making them are as follows: AgₓM_{y} (Refs. 29 and 118-124); BiₓM_{y} (Refs. 125-134, 135 and 136-137); CoₓM_{y} (Ref. 138); CuₓM_{y} (Refs. 139 and 140); MnM (Ref. 141); NiM₂ (Ref. 142); PbM (Refs. 114 and 143-152); and 5 nM (Refs. 153 and 154). M is Se, S or Te. The numbers for x and y are known in the art and typically will range from 1 to 9.

Nanowires made from ternary chalcogenides using known procedures may also be used to form the network 18. Exemplary ternary chalcogenide nanowires and references to the details for making them are as follows: CuInM (Ref. 155); AgSnM (Ref 156); CdMnM (Ref. 141); and CdZnM (Ref 157) where M also can be Se, S or Te.

Nanowires (also referred to as nanofibers) made from conducting polymers may be used to form network 18. Exemplary conducting polymer nanowires and references to the details for making them are as follows: polyaniline (Refs. 82 and 158-167); polypyrrole (Refs. 158, 160 and 168-170); and polythiophene (Refs. 158, 169 and 171-173).

The exemplary nanowires described above are deposited on the insulating layer 20 using any of the known techniques for forming a network of nanowires on a surface. Exemplary deposition methods that can be used to form nanowire networks on substrates include the following:

1. Solution Casting:

A great variety of nanowires can be made in solution and cast onto a substrate. See Refs. 28, 29, 50, 64, 68, 75, 96, 126, 131, 140, 143, 153 and 174-194 for details of exemplary procedures that may be used to make solutions of nanowires. These nanowires can be readily deposited onto an FET device by drop casting. Upon drying the solvent, network structures form. For example, we deposited a polyaniline nanowire network on a silicon wafer cast from a water dispersion using the procedure described in detail in Ref. 164. A scanning electron microscopy image of the resulting polyaniline nanowire network is shown in FIG. 2.

2. Langmuir-Blodgett Techniques:

Nanowires self-assemble into interconnecting networks when organic solvents containing nanowires are spread onto a water surface. The network can then be transferred from the water surface to a solid substrate by Langmuir-Blodgett techniques. Details of such procedures are set forth in Refs. 195-197.

3. Direct Growth of Nanowires by Chemical Vapor Deposition (CVD):

Using chemical vapor deposition, some nanowires can be directly grown as networks on substrates as diagrammatically shown in FIG. 5. Details of an exemplary CVD procedure for forming a network of nanowires as set forth in Ref. 198.

4. Electrospinning.

In a similar fashion to spider web networks, electrospining has been demonstrated to form networks of polymer nanowires/fibers on solid substrates (see Refs. 199 and 200). In a typical process, a polymeric melt or solution is extruded from the orifice of a needle to form a small droplet. In the presence of a strong electric field, charges built up on the surface of the droplet will overcome the surface tension to induce the formation of a liquid jet that is subsequently accelerated toward a grounded target. As the solvent is evaporating, this liquid jet is stretched to many times its original length to produce nanofibers (nanowires) of the polymer. The nanofibers are collected as inter-weaving networks on a spinning target.

Networks in accordance with the present invention are composed of an interconnected collection of two or more one-dimensional nanostructures (including nanowires/rods/fibers/tubes and the like) that establish at least one continuous pathway from the source 12 to drain 14. The nanowires may include dopants, if desired. Exemplary dopants for polyaniline include any Bronsted or Lewis acid, such as described in U.S. Pat. No. 5,096,586 issued Mar. 17, 1992. See especially from line 21 in column 8 to line 14 in column 9.

Examples of practice are as follows:

Polyaniline nanofiber networks were prepared using the same procedure as set forth in Ref. 164 and used to make nanoscale transistors of the type shown in FIG. 1. The films of polyaniline nanofiber networks were deposited on an epoxy insulated packaged silicon die with source and drain contacts. Gating was provided by an electrode and the network covered with a liquid (water). This type of gating configuration has been used for carbon nanotube based devices for the demonstration of transistor operation (See Ref. 202).

The dependence of the source-drain current I_{sd} on the source-drain voltage V_{sd}, (I_{sd}-V_{sd}) together with the dependence of I_{sd} on the gate voltage I_{g} (the I_{sd}-V_{g} characteristics) were measured. The device was exposed to 100 mM HCl, and subsequently the I_{sd}-V_{g} curves were measured. In order to avoid strong gate to drain current leakage the gate frequency was kept below 0.1 Hz, V_{g} amplitude around 0.3V. The concentration of HCl was chosen to have a detectable source—drain current at low (V_{sd}≦50 mV) bias. With these parameters the leak current was observed to be below 20 nA.

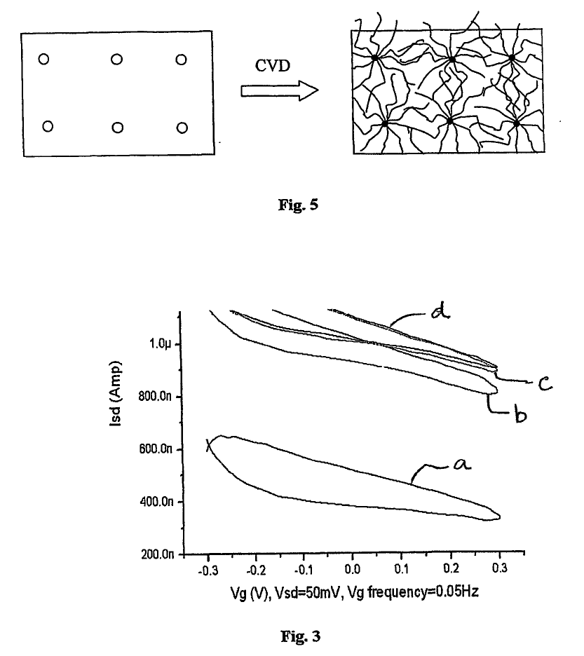

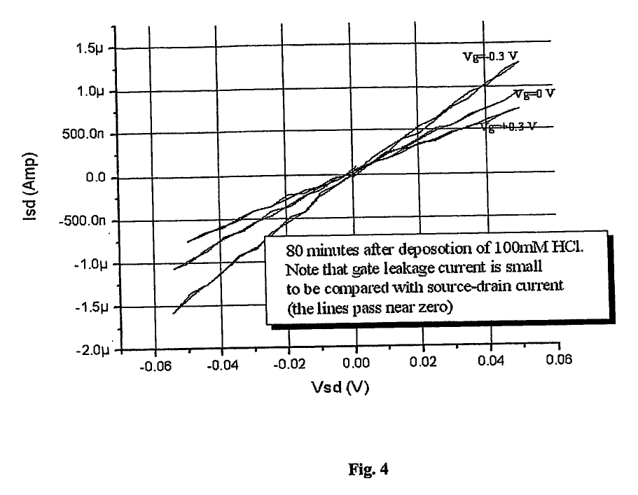

In the first one hour after the application of HCl the I-V_{g} curves “shifted upwards” as shown on FIG. 3. In FIG. 3, the curve labeled “a” was obtained right after deposition of the HCl. The curve labeled “b” was obtained at 45 minutes after deposition. The curves labeled “c” and “d” were obtained at 60 and 75 minutes after deposition, respectively. The behavior as shown in FIG. 3 is expected and is due to HCl doping of the polyaniline fibers. When the response stabilized, I_{sd} (V_{sd}) curves were taken at several fixed gate voltages and the results are shown in FIG. 4. The dependence of the source-drain conductance again is consistent with a transistor operation with a p-type conducting channel. As a consistency check, HCl was replaced with an ammonia solution. The ammonia solution removes the dopants and leads to an insulating network, with resistance changing from 100 kΩ to 1 GΩ.

The preceding example showing the use of a network of molecular nanowires in accordance with the present invention demonstrates: field effect transistor (FET) operation; establishes a route for device optimization through doping; and further establishes that these devices can be used as sensors in a liquid environment.

Some of the advantages of semiconductor devices that utilize the network of molecular nanowires in accordance with the present invention include: 1) simple fabrication of nanowires or nanofibers, no need for CVD growth; 2) selected quasi one-dimensional conduction path; 3) chemically tunable conducting properties; and 4) such wires are robust and flexible, allowing integration onto flexible surfaces.

The advantages provided by using networks of molecular nanowires include: 1) many nanowires act as the conducting element, statistical averaging will occur, strongly reducing the signal variation from device to device; 2) by virtue of the large number of molecular nanowires involved, the structure is also “defect tolerant”. In case of sensor applications, the advantages include: 1) the surface area is large; 2) the conducting path is sensitive to environmental changes; and 3) the size of the nanowires is compatible with biomolecules.

Having thus described exemplary embodiments of the present invention, it should be noted by those skilled in the art that the within disclosures are exemplary only and that various other alternatives, adaptations and modifications may be made within the scope of the present invention. Accordingly, the present invention is not limited to the above preferred embodiments and examples, but is only limited by the following claims.

### BIBLIOGRAPHY

1. Banerjee, S., Dan, A. & Chakravorty, D. Synthesis of conducting nanowires. Journal of Materials Science 37, 4261-4271 (2002).
2. Barsotti, R. J. et al. Imaging, structural, and chemical analysis of silicon nanowires. Applied Physics Letters 81, 2866-2868 (2002).
3. Carim, A. H., Lew, K. K. & Redwing, J. M. Bicrystalline silicon nanowires. Advanced Materials 13, 1489-+ (2001).
4. Chung, S. W., Yu, J. Y. & Heath, J. R. Silicon nanowire devices. Applied Physics Letters 76, 2068-2070 (2000).
5. Cui, Y., Lauhon, L. J., Gudiksen, M. S., Wang, J. F. & Lieber, C. M. Diameter-controlled synthesis of single-crystal silicon nanowires. Applied Physics Letters 78, 2214-2216 (2001).
6. Gole, J. L., Stout, J. D., Rauch, W. L. & Wang, Z. L. Direct synthesis of silicon nanowires, silica nanospheres, and wire-like nanosphere agglomerates. Applied Physics Letters 76, 2346-2348 (2000).
7. Gu, Q., Dang, H. Y., Cao, J., Zhao, J. H. & Fan, S. S. Silicon nanowires grown on iron-patterned silicon substrates. Applied Physics Letters 76, 3020-3021 (2000).
8. Gudiksen, M. S., Lauhon, L. J., Wang, J., Smith, D. C. & Lieber, C. M. Growth of nanowire superlattice structures for nanoscale photonics and electronics. Nature 415, 617-620 (2002).
9. Hanrath, T. & Korgel, B. A. Supercritical fluid-liquid-solid (SFLS) synthesis of Si and Ge nanowires seeded by colloidal metal nanocrystals. Advanced Materials 15, 437-440 (2003).
10. Lew, K. K., Reuther, C., Carim, A. H., Redwing, J. M. & Martin, B. R. Template-directed vapor-liquid-solid growth of silicon nanowires. Journal of Vacuum Science & Technology B 20, 389-392 (2002).
11. Lew, K. K. & Redwing, J. M. Growth characteristics of silicon nanowires synthesized by vapor-liquid-solid growth in nanoporous alumina templates. Journal of Crystal Growth 254, 14-22 (2003).
12. Liu, Z. Q. et al. Synthesis of silicon nanowires using AuPd nanoparticles catalyst on silicon substrate. Journal of Physics and Chemistry of Solids 61, 1171-1174 (2000).
13. Morales, A. M. & Lieber, C. M. Rational synthesis of silicon nanowires. Abstracts of Papers of the American Chemical Society 213, 651-Inor (1997).
14. Shi, W. S. et al. Synthesis of large areas of highly oriented, very long silicon nanowires. Advanced Materials 12, 1343-1345 (2000).
15. Sunkara, M. K., Sharma, S., Miranda, R., Lian, G. & Dickey, E. C. Bulk synthesis of silicon nanowires using a low-temperature vapor-liquid-solid method. Applied Physics Letters 79, 1546-1548 (2001).
16. Zhang, Y. J. et al. A simple method to synthesize nanowires. Chemistry of Materials 14, 3564-3568 (2002).
17. Wu, Y. Y., Fan, R. & Yang, P. D. Block-by-block growth of single-crystalline Si/SiGe superlattice nanowires. Nano Letters 2, 83-86 (2002).
18. Yu, D. P. et al. Nanoscale silicon wires synthesized using simple physical evaporation. Applied Physics Letters 72, 3458-3460 (1998).
19. Yu, J. Y., Chung, S. W. & Heath, J. R. Silicon nanowires: Preparation, device fabrication, and transport properties. Journal of Physical Chemistry B 104, 11864-11870 (2000).
20. Yu, D. P. et al. Controlled growth of oriented amorphous silicon nanowires via a solid-liquid-solid (SLS) mechanism. Physica E 9, 305-309 (2001).
21. Zhang, Y. J. et al. Synthesis of thin Si whiskers (nanowires) using SiCl4. Journal of Crystal Growth 226, 185-191 (2001).
22. Coleman, N. R. B., Ryan, K. M., Spalding, T. R., Holmes, J. D. & Morris, M. A. The formation of dimensionally ordered germanium nanowires within mesoporous silica. Chemical Physics Letters 343, 1-6 (2001).
23. Morales, A. M. & Lieber, C. M. A laser ablation method for the synthesis of crystalline semiconductor nanowires. Science 279, 208-211 (1998).
24. Ryan, K. M., Erts, D., Olin, H., Morris, M. A. & Holmes, J. D. Three dimensional architectures of ultra-high density semiconducting nanowires deposited on chip. Journal of the American Chemical Society 125, 6284-6288 (2003).
25. Ye, C. H., Meng, G. W., Zhang, L. D., Wang, G. Z. & Wang, Y. H. A facile vapor-solid synthetic route to Sb₂O₃ fibrils and tubules. Chemical Physics Letters 363, 34-38 (2002).
26. Wu, Y. Y. & Yang, P. D. Germanium/carbon core-sheath nanostructures. Applied Physics Letters 77, 43-45 (2000).
27. Wu, Y. Y. & Yang, P. D. Germanium nanowire growth via simple vapor transport. Chemistry of Materials 12, 605-+ (2000).
28. Gates, B., Mayers, B., Cattle, B. & Xia, Y. N. Synthesis and characterization of uniform nanowires of trigonal selenium. Advanced Functional Materials 12, 219-227 (2002).
29. Gates, B. et al. Synthesis and characterization of crystalline Ag₂Se nanowires through a template-engaged reaction at room temperature. Advanced Functional Materials 12, 679-686 (2002).
30. Gates, B., Mayers, B., Grossman, A. & Xia, Y. N. A sonochemical approach to the synthesis of crystalline selenium nanowires in solutions and on solid supports. Advanced Materials 14, 1749-+ (2002).
31. Bae, S. Y., Seo, H. W., Park, J., Yang, H. & Song, S. A. Synthesis and structure of gallium nitride nanobelts. Chemical Physics Letters 365, 525-529 (2002).
32. Chang, K. W. & Wu, J. J. Low-temperature catalytic synthesis gallium nitride nanowires. Journal of Physical Chemistry B 106, 7796-7799 (2002).
33. Chen, X. L. et al. Straight and smooth GaN nanowires. Advanced Materials 12, 1432-1434 (2000).
34. Chen, C. C. & Yeh, C. C. Large-scale catalytic synthesis of crystalline gallium nitride nanowires. Advanced Materials 12, 738-+ (2000).
35. Chen, C. C. et al. Catalytic growth and characterization of gallium nitride nanowires. Journal of the American Chemical Society 123, 2791-2798 (2001).
36. Cheng, G. S. et al. Large-scale synthesis of single crystalline gallium nitride nanowires. Applied Physics Letters 75, 2455-2457 (1999).
37. Cheng, G. S., Chen, S. H., Zhu, X. G., Mao, Y. Q. & Zhang, L. D. Highly ordered nanostructures of single crystalline GaN nanowires in anodic alumina membranes. Materials Science and Engineering a-Structural Materials Properties Microstructure and Processing 286, 165-168 (2000).
38. Gudiksen, M. S., Wang, J. F. & Lieiber, C. M. Synthetic control of the diameter and length of single crystal semiconductor nanowires. Journal of Physical Chemistry B 105, 4062-4064 (2001).
39. Lin, H. M. et al. Synthesis and characterization of core-shell GaP@GaN and GaN@GaP nanowires. Nano Letters 3, 537-541 (2003).
40. Lyu, S. C. et al. Catalytic synthesis and photoluminescence of gallium nitride nanowires. Chemical Physics Letters 367, 136-140 (2003).
41. Peng, H. Y. et al. Bulk-quantity GaN nanowires synthesized from hot filament chemical vapor deposition. Chemical Physics Letters 327, 263-270 (2000).
42. Shi, W. S., Zheng, Y. F., Wang, N., Lee, C. S. & Lee, S. T. A general synthetic route to III-V compound semiconductor nanowires. Advanced Materials 13, 591-+ (2001).
43. Tang, C. C., Fan, S. S., Dang, H. Y., Li, P. & Liu, Y. M. Simple and high-yield method for synthesizing single-crystal GaN nanowires. Applied Physics Letters 77, 1961-1963 (2000).
44. Xiang, B. et al. Green-light-emitting ZnSe nanowires fabricated via vapor phase growth. Applied Physics Letters 82, 3330-3332 (2003).
45. Zhang, J. et al. Fabrication and photoluminescence of ordered GaN nanowire arrays. Journal of Chemical Physics 115, 5714-5717 (2001).
46. Lyu, S. C., Zhang, Y., Ruh, H., Lee, H. J. & Lee, C. J. Synthesis of high-purity GaP nanowires using a vapor deposition method. Chemical Physics Letters 367, 717-722 (2003).
47. Shi, W. S., Zheng, Y. F., Wang, N., Lee, C. S. & Lee, S. T. Synthesis and microstructure of gallium phosphide nanowires. Journal of Vacuum Science & Technology B 19, 1115-1118 (2001).
48. Shi, W. S., Zheng, Y. F., Wang, N., Lee, C. S. & Lee, S. T. Oxide-assisted growth and optical characterization of gallium-arsenide nanowires. Applied Physics Letters 78, 3304-3306 (2001).
49. Duan, X. F., Wang, J. F. & Lieber, C. M. Synthesis and optical properties of gallium arsenide nanowires. Applied Physics Letters 76, 1116-1118 (2000).
50. Yu, H. & Buhro, W. E. Solution-liquid-solid growth of soluble GaAs nanowires. Advanced Materials 15, 416-+ (2003).
51. Liang, C. H. et al. Selective-area growth of indium nitride nanowires on gold-patterned Si(100) substrates. Applied Physics Letters 81, 22-24 (2002).
52. Bakkers, E. P. A. M. & Verheijen, M. A. Synthesis of InP nanotubes. Journal of the American Chemical Society 125, 3440-3441 (2003).
53. Hogan, H. InP nanowires act as detectors. Photonics Spectra 36, 30-30 (2002).
54. Wang, J. F., Gudiksen, M. S., Duan, X. F., Cui, Y. & Lieber, C. M. Highly polarized photoluminescence and photodetection from single indium phosphide nanowires. Science 293, 1455-1457 (2001).
55. He, M. Q. et al. InAs nanowires and whiskers grown by reaction of indium with GaAs. Applied Physics Letters 82, 3749-3751 (2003).
56. Wu, Q. S., Zheng, N. W., Ding, Y. P. & Li, Y. D. Micelle-template inducing synthesis of winding ZnS nanowires. Inorganic Chemistry Communications 5, 671-673 (2002).
57. Wang, Y., Zhang, L., Liang, C., Wang, G. & Peng, X. Catalytic growth and photoluminescence properties of semiconductor single-crystal ZnS nanowires. Chemical Physics Letters 357, 314-318 (2002).
58. Li, Y., Wan, J. H. & Gu, Z. N. Synthesis of ZnS nanowires in liquid crystal systems. Molecular Crystals and Liquid Crystals 337, 193-196 (1999).
59. Duan, X. & Lieber, C. M. General synthesis of compound semiconductor nanowires. Advanced Materials (Weinheim, Germany) 12, 298-302 (2000).
60. Deng, Z. X., Li, L. B. & Li, Y. D. Novel inorganic-organic-layered structures: Crystallographic understanding of both phase and morphology formations of one-dimensional CdE (E=S, Se, Te) nanorods in ethylenediamine. Inorganic Chemistry 42, 2331-2341 (2003).
61. Cao, H. Q. et al. Sol-gel template synthesis of an array of single crystal CdS nanowires on a porous alumina template. Advanced Materials 13, 1393-1394 (2001).
62. Chen, Y. T., Guo, Y., Kong, L. B. & Li, H. L. A solid-state reaction for the synthesis of CdS nanowires. Chemistry Letters, 602-603 (2002).
63. Gao, F., Lu, Q. Y. & Zhao, D. Y. Ligand-assisted solvothermal growth of CdS nanowires. Chemistry Letters, 732-733 (2002).
64. He, J., Zhao, X. N., Zhu, J. J. & Wang, J. Preparation of CdS nanowires by the decomposition of the complex in the presence of microwave irradiation. Journal of Crystal Growth 240, 389-394 (2002).
65. Klein, J. D. et al. Electrochemical Fabrication of Cadmium Chalcogenide Microdiode Arrays. Chemistry of Materials 5, 902-904 (1993).
66. Li, Y., Wan, J. H. & Gu, Z. N. Templated synthesis of CdS nanowires in hexagonal liquid crystal systems. Acta Physico-Chimica Sinica 15, 1-4 (1999).
67. Li, Y., Wan, J. H. & Gu, Z. N. The formation of cadmium sulfide nanowires in different liquid crystal systems. Materials Science and Engineering a-Structural Materials Properties Microstructure and Processing 286, 106-109 (2000).
68. Peng, X. S. et al. Synthesis of highly ordered CdSe nanowire arrays embedded in anodic alumina membrane by electrodeposition in ammonia alkaline solution. Chemical Physics Letters 343, 470-474 (2001).
69. Tang, K. B., Qian, Y. T., Zeng, J. H. & Yang, X. G. Solvothermal route to semiconductor nanowires. Advanced Materials 15, 448-450 (2003).
70. Wang, Y. H., Xu, Y. Q., Cai, W. L. & Mo, J. M. New method to prepare CdS nanowire arrays. Acta Physico-Chimica Sinica 18, 943-946 (2002).
71. Xie, Y., Yan, P., Lu, J., Qian, Y. T. & Zhang, S. Y. CdS/CdSe core/sheath nanostructures obtained from CdS nanowires. Chemical Communications, 1969-1970 (1999).
72. Zhan, J. H. et al. Polymer-controlled growth of CdS nanowires. Advanced Materials 12, 1348-1351 (2000).
73. Yang, Q., Tang, K. B., Wang, C. R., Qian, Y. T. & Zhang, S. Y. PVA-assisted synthesis, and characterization of CdSe and CdTe nanowires. Journal of physical Chemistry B 106, 9227-9230 (2002).
74. Zhao, A. W. et al. Electrochemical synthesis of ordered CdTe nanowire arrays. Applied Physics a-Materials Science & Processing 76, 537-539 (2003).
75. Shao, M. W., Kong, L. F., Li, Q., Yu, W. C. & Qian, Y. T. Microwave-assisted synthesis of tube-like HgS nanoparticles in aqueous solution under ambient condition. Inorganic Chemistry Communications 6, 737-739 (2003).
76. Dai, Z. R., Pan, Z. W. & Wang, Z. L. Novel nanostructures of functional oxides synthesized by thermal evaporation. Advanced Functional Materials 13, 9-24 (2003).
77. Wang, Z. L., Pan, Z. W. & Dai, Z. R. Structures of oxide nanobelts and nanowires. Microscopy and Microanalysis 8, 467-474 (2002).
78. Peng, X. S. et al. Novel method synthesis of CdO nanowires. Journal of physics D-Applied Physics 35, L101-L104 (2002).
79. Han, W. Q., Kohler-Redlich, P., Ernst, F. & Ruhle, M. Growth and microstructure of Ga₂O₃ nanorods. Solid State Communications 115, 527-529 (2000).
80. Hu, J. Q., Li, Q., Meng, X. M., Lee, C. S. & Lee, S. T. Synthesis of beta-Ga₂O₃ nanowires by laser ablation. Journal of Physical Chemistry B 106, 9536-9539 (2002).
81. Gao, Y. H., Bando, Y., Sato, T., Zhang, Y. F. & Gao, X. Q. Synthesis, Raman scattering and defects of beta-Ga₂O₃ nanorods. Applied Physics Letters 81, 2267-2269 (2002).
82. Li, J. Y., Chen, X. L., Zhang, G. & Lee, J. Synthesis and structure of Ga₂O₃ nanosheets. Modern Physics Letters B 16, 409-414 (2002).
83. Patzke, G. R., Krumeich, F. & Nesper, R. Oxidic nanotubes and nanorods—Anisotropic modules for a future nanotechnology. Angewandte Chemie-International Edition 41, 2446-2461 (2002).
84. Li, J. Y., Chen, X. L., Qiao, Z. Y., He, M. & Li, H. Large-scale synthesis of single-crystalline beta-Ga₂O₃ nanoribbons, nanosheets and nanowires. Journal of Physics-CondensedMatter 13, L937-L941 (2001).
85. Cheng, B. & Samulski, E. T. Fabrication and characterization of nanotubular semiconductor oxides In₂O₃ and Ga₂O₃. Journal of Materials Chemistry 11, 2901-2902 (2001).
86. Liang, C. H. et al. Catalytic synthesis and photoluminescence of beta-Ga₂O₃ nanowires. Applied Physics Letters 78, 3202-3204 (2001).
87. Li, J. Y. et al. Synthesis of beta-Ga₂O₃ nanorods. Journal of Alloys and Compounds 306, 300-302 (2000).
88. Zhang, H. Z. et al. Ga₂O₃ nanowires prepared by physical evaporation. Solid State Communications 109, 677-682 (1999).
89. Wu, X. C., Hong, J. M., Han, Z. J. & Tao, Y. R. Fabrication and photoluminescence characteristics of single crystalline In₂O₃ nanowires. Chemical Physics Letters 373, 28-32 (2003).
90. Li, Y. B., Bando, Y. & Golberg, D. Single-crystalline In₂O₃ nanotubes filled with In. Advanced Materials 15, 581-585 (2003).
91. Zhang, J., Qing, X., Jiang, F. H. & Dai, Z. H. A route to Ag-catalyzed growth of the semiconducting In₂O₃ nanowires. Chemical Physics Letters 371, 311-316 (2003).
92. Jeong, J. S., Kim, Y. H. & Lee, J. Y. Morphology and structure of nano-sized In₂O₃ crystals synthesized by wet reaction. Journal of the Korean Physical Society 42, S254-S257 (2003).
93. Li, C. et al. Diameter-controlled growth of single-crystalline In₂O₃ nanowires and their electronic properties. Advanced Materials 15, 143-+ (2003).
94. Chen, Y. Q. et al. Bulk-quantity synthesis and self-catalytic VLS growth of SnO₂ nano-wires by lower-temperature evaporation. Chemical Physics Letters 369, 16-20 (2003).
95. Li, C. et al. In₂O₃ nanowires as chemical sensors. Applied Physics Letters 82, 1613-1615 (2003).
96. Dai, L. et al. Fabrication and characterization of In₂O₃ nanowires. Applied Physics a-Materials Science & Processing 75, 687-689 (2002).
97. Peng, X. S. et al. Synthesis and photoluminescence of single-crystalline In₂O₃ nanowires. Journal of Materials Chemistry 12, 1602-1605 (2002).
98. Peng, X. S. et al. Large-scale synthesis of In₂O₃ nanowires. Applied Physics a-Materials Science & Processing 74, 437-439 (2002).
99. Liang, C. H., Meng, G. W., Lei, Y., Phillipp, F. & Zhang, L. D. Catalytic growth of semiconducting In₂O₃ nanofibers. Advanced Materials 13, 1330-1333 (2001).
100. Liu, Y., Liu, Z. & Wang, G. Preparation of Mn₃O₄ nanowires by calcining the precursor powders synthesized in a novel inverse microemulsion. Applied Physics a-Materials Science & Processing 76, 1117-1120 (2003).
101. Xiong, Y. J., Xie, Y., Li, Z. Q. & Wu, C. Z. Growth of well-aligned gamma-MnO₂ monocrystalline nanowires through a coordination-polymer-precursor route. Chemistry-a European Journal 9, 1645-1651 (2003).
102. Wang, X. & Li, Y. D. Synthesis and formation mechanism of manganese dioxide nanowires/nanorods. Chemistry-a European Journal 9, 300-306 (2003).
103. Xu, C. K., Xu, G. D. & Wang, G. H. Preparation and characterization of NiO nanorods by thermal decomposition of NiC₂O₄ precursor. Journal of Materials Science 38, 779-782 (2003).
104. Pan, Z. W., Dai, Z. R. & Wang, Z. L. Lead oxide nanobelts and phase transformation induced by electron beam irradiation. Applied Physics Letters 80, 309-311 (2002).
105. Xu, C. K., Zhao, X. L., Liu, S. & Wang, G. H. Large-scale synthesis of rutile SnO₂ nanorods. Solid State Communications 125, 301-304 (2003).
106. Peng, X. S. et al. Micro-Raman and infrared properties of SnO₂ nanobelts synthesized from Sn and SiO₂ powders. Journal of Applied Physics 93, 1760-1763 (2003).
107. Liu, Y. K., Dong, Y. & Wang, G. H. Far-infrared absorption spectra and properties of SnO₂ nanorods. Applied Physics Letters 82, 260-262 (2003).
108. Sun, S. H. et al. Large-scale synthesis of SnO₂ nanobelts. Applied Physics a-Materials Science & Processing 76, 287-289 (2003).
109. Wang, W. Z., Xu, C. K., Wang, G. H., Liu, Y. K. & Zheng, C. L. Synthesis and Raman scattering study of rutile SnO₂ nanowires. Journal of Applied Physics 92, 2740-2742 (2002).
110. Jian, J. K., Chen, X. L., Wang, W. J., Dai, L. & Xu, Y. P. Growth and morphologies of large-scale SnO₂ nanowires, nanobelts and nanodendrites. Applied Physics a-Materials Science & Processing 76, 291-294 (2003).
111. Leite, E. R. et al. Synthesis of SnO₂ nanoribbons by a carbothermal reduction process. Journal of Nanoscience and Nanotechnology 2, 125-128 (2002).
112. Hu, J. Q. et al. Large-scale rapid oxidation synthesis of SnO₂ nanoribbons. Journal of Physical Chemistry B 106, 3823-3826 (2002).
113. Lyu, S. C. et al. Low temperature growth and photoluminescence of well-aligned zinc oxide nanowires. Chemical Physics Letters 363, 134-138 (2002).
114. Liu, C. H. et al. High-density, ordered ultraviolet light-emitting ZnO nanowire arrays. Advanced Materials 15, 838-+ (2003).
115. Yang, P. D. et al. Controlled growth of ZnO nanowires and their optical properties. Advanced Functional Materials 12, 323-331 (2002).
116. Liu, S. C. & Wu, J. J. Low-temperature and catalyst-free synthesis of well-aligned ZnO nanorods on Si (100). Journal of Materials Chemistry 12, 3125-3129 (2002).
117. Tseng, Y. K., Lin, I. N., Liu, K. S., Lin, T. S. & Chen, I. C. Low-temperature growth of ZnO nanowires. Journal of Materials Research 18, 714-718 (2003).
118. Xiao, J. P., Xie, Y., Tang, R. & Luo, W. Template-based synthesis of nanoscale Ag₂E (E=S, Se) dendrites. Journal of Materials Chemistry 12, 1148-1151 (2002).
119. Gates, B., Wu, Y. Y., Yin, Y. D., Yang, P. D. & Xia, Y. N. Single-crystalline nanowires of Ag₂Se can be synthesized by templating against nanowires of trigonal Se. Journal of the American Chemical Society 123, 11500-11501 (2001).
120. Peng, X. S. et al. Electrochemical fabrication of ordered Ag₂S nanowire arrays. Materials Research Bulletin 37, 1369-1375 (2002).
121. Lu, Q. Y., Gao, F. & Zhao, D. Y. Creation of a unique self-supported pattern of radially aligned semiconductor Ag₂S nanorods. Angewandte Chemie-International Edition 41, 1932-+ (2002).
122. Glanville, Y. J., Narehood, D. G., Sokol, P. E., Amma, A. & Mallouk, T. Preparation and synthesis of Ag₂Se nanowires produced by template directed synthesis. Journal of Materials Chemistry 12, 2433-2434 (2002).
123. Chen, R. Z., Xu, D. S., Guo, G. L. & Gui, L. L. Silver selenide nanowires by electrodeposition. Journal of the Electrochemical Society 150, G183-G186 (2003).
124. Chen, R. Z., Xu, D. S., Guo, G. L. & Gui, L. L. Silver telluride nanowires prepared by dc electrodeposition in porous anodic alumina templates. Journal of Materials Chemistry 12, 2435-2438 (2002).
125. He, R., Qian, X. F., Yin, J. & Zhu, Z. K. Preparation of Bi₂S₃ nanowhiskers and their morphologies. Journal of Crystal Growth 252, 505-510 (2003).
126. Zhou, S. X., Li, J. M., Ke, Y. X. & Lu, S. M. Synthesis of bismuth sulfide nanorods in acidic media at room temperature. Materials Letters 57, 2602-2605 (2003).
127. Shen, G. Z., Chen, D., Tang, K. B., Li, F. Q. & Qian, Y. T. Large-scale synthesis of uniform urchin-like patterns of Bi₂S₃ nanorods through a rapid polyol process. Chemical Physics Letters 370, 334-337 (2003).
128. Wang, D. B., Shao, M. W., Yu, D. B., Li, G. P. & Qian, Y. T. Polyol-mediated preparation of Bi₂S₃ nanorods. Journal of Crystal Growth 243, 331-335 (2002).
129. Wang, H., Zhu, J. J., Zhu, J. M. & Chen, H. Y. Sonochemical method for the preparation of bismuth sulfide nanorods. Journal of Physical Chemistry B 106, 3848-3854 (2002).
130. Peng, X. S. et al. Electrochemical fabrication of ordered Bi₂S₃ nanowire arrays. Journal of Physics D-Applied Physics 34, 3224-3228 (2001).
131. Liao, X. H., Wang, H., Zhu, J. J. & Chen, H. Y. Preparation of Bi₂S₃ nanorods by microwave irradiation. Materials Research Bulletin 36, 2339-2346 (2001).
132. Zhang, W. X. et al. Low temperature growth of bismuth sulfide nanorods by a hydrothermal method. Solid State Communications 119, 143-146 (2001).
133. Yang, J. et al. Pressure-controlled fabrication of stibnite nanorods by the solvothermal decomposition of a simple single-source precursor. Chemistry of Materials 12, 2924-2929 (2000).
134. Yu, S. H. et al. A solvothermal decomposition process for fabrication and particle sizes control of Bi₂S₃ nanowires. Journal of Materials Research 14, 4157-4162 (1999).
135. Wang, D. B., Yu, D. B., Mo, M. S., Liu, X. M. & Qian, Y. T. Preparation and characterization of wire-like Sb₂Se₃ and flake-like Bi₂Se₃ nanocrystals. Journal of Crystal Growth 253, 445-451 (2003).
136. Deng, Y., Wei, G. D. & Nan, C. W. Ligand-assisted control growth of chainlike nanocrystals. Chemical Physics Letters 368, 639-643 (2003).
137. Sander, M. S., Gronsky, R., Sands, T. & Stacy, A. M. Structure of bismuth telluride nanowire arrays fabricated by electrodeposition into porous anodic alumina templates. Chemistry of Materials 15, 335-339 (2003).
138. Peng, Q., Dong, Y. J. & Li, Y. D. Synthesis of uniform CoTe and NiTe semiconductor nanocluster wires through a novel coreduction method. Inorganic Chemistry 42, 2174-2175 (2003).
139. Lu, Q. Y., Gao, F. & Zhao, D. Y. One-step synthesis and assembly of copper sulfide nanoparticles to nanowires, nanotubes, and nanovesicles by a simple organic amine-assisted hydrothermal process. Nano Letters 2, 725-728 (2002).
140. Xu, C. Q., Zhang, Z. C., Ye, Q. & Liu, X. Synthesis of copper sulfide nanowhisker via sonochemical way and its characterization. Chemistry Letters 32, 198-199 (2003).
141. Jun, Y. W., Jung, Y. Y. & Cheon, J. Architectural control of magnetic semiconductor nanocrystals. Journal of the American Chemical Society 124, 615-619 (2002).
142. Li, B., Xie, Y., Huang, J. X., Su, H. L. & Qian, Y. Solvothermal synthesis to NiE₂ (E=Se, Te) nanorods at low temperature. Nanostructured Materials 11, 1067-1071 (1999).
143. Wang, D. B., Yu, D. B., Mo, M. S., Liu, X. M. & Qian, Y. T. Hydrothermal preparation of one-dimensional assemblies of PbS nanoparticles. Solid State Communications 125, 475-479 (2003).
144. Leontidis, E., Orphanou, M., Kyprianidou-Leodidou, T., Krumeich, F. & Caseri, W. Composite nanotubes formed by self-assembly of PbS nanoparticles. Nano Letters 3, 569-572 (2003).
145. Yu, D. B., Wang, D. B., Meng, Z. Y., Lu, J. & Qian, Y. T. Synthesis of closed PbS nanowires with regular geometric morphologies. Journal of Materials Chemistry 12, 403-405 (2002).
146. Chen, M., Xie, Y., Yao, Z. Y., Liu, X. M. & Qian, Y. T. Highly-oriented recrystallization of PbS nanoparticles in a solvothermal process. Materials Chemistry and Physics 74, 109-111 (2002).
147. Qiao, Z. P. et al. Synthesis of lead sulfide/(polyvinyl acetate) nanocomposites with controllable morphology. Chemical Physics Letters 321, 504-507 (2000).
148. Wang, S. H. & Yang, S. H. Preparation and characterization of oriented PbS crystalline nanorods in polymer films. Langmuir 16, 389-397 (2000).
149. Nanda, K. K., Kruis, F. E. & Fissan, H. Energy levels in embedded semiconductor nanoparticles and nanowires. Nano Letters 1, 605-611 (2001).
150. Wang, W. H., Geng, Y., Qian, Y., Ji, M. R. & Liu, X. M. A novel pathway to PbSe nanowires at room temperature. Advanced Materials 10, 1479-1481 (1998).
151. Cho, K. S., Gaschler, W. L., Murray, C. B. & Stokes, K. L. PBSE nanocrystals, nanowires and superlattices. Abstracts of Papers of the American Chemical Society 224, U308-U308 (2002).
152. Chen, M., Xie, Y., Lu, J. C., Zhu, Y. J. & Qian, Y. T. A novel two-step radiation route to PbSe crystalline nanorods. Journal of Materials Chemistry 11, 518-520 (2001).
153. An, C. H. et al. Shape-selected synthesis of nanocrystalline SnS in different alkaline media. Journal of Crystal Growth 252, 581-586 (2003).
154. Shen, G. Z. et al. Rapid synthesis of SnSe nanowires via an ethylenediamine-assisted polyol route. Chemistry Letters 32, 426-427 (2003).
155. Jiang, Y. et al. Elemental solvothermal reaction to produce ternary semiconductor CuInE₂ (E=S, Se) nanorods. Inorganic Chemistry 39, 2964-+ (2000).
156. Jin, Y., Tang, K. B., An, C. H. & Huang, L. Y. Hydrothermal synthesis and characterization of AgInSe₂ nanorods. Journal of Crystal Growth 253, 429-434 (2003).
157. Zhou, S. M., Feng, Y. S. & Zhang, L. D. Growth and optical characterization of large-scale crystal CdₓZn₁₋ₓS whiskers via vapor reaction. Journal of Crystal Growth 252, 1-3 (2003).
158. Joo, J. et al. Conducting polymer nanotube and nanowire synthesized by using nanoporous template: Synthesis, characteristics, and applications. Synthetic Metals 135, 7-9 (2003).
159. He, H. X., Li, C. Z. & Tao, N. J. Conductance of polymer nanowires fabricated by a combined electrodeposition and mechanical break junction method. Applied Physics Letters 78, 811-813 (2001).
160. Choi, S. J. & Park, S. M. Electrochemical growth of nanosized conducting polymer wires on gold using molecular templates. Advanced Materials 12, 1547-1549 (2000).
161. Hassanien, A., Gao, M., Tokumoto, M. & Dai, L. Scanning tunneling microscopy of aligned coaxial nanowires of polyaniline passivated carbon nanotubes. Chemical Physics Letters 342, 479-484 (2001).
162. Huang, K. & Wan, M. X. Self-assembled nanostructural polyaniline doped with azobenzenesulfonic acid. Synthetic Metals 135, 173-174 (2003).
163. Wan, M. X. et al. Studies on nanostructures of conducting polymers via self-assembly method. Synthetic Metals 135, 175-176 (2003).
164. Huang, J. X., Viiji, S., Weiller, B. H. & Kaner, R. B. Polyaniline nanofibers: Facile synthesis and chemical sensors. Journal of the American Chemical Society 125, 314-315 (2003).
165. He, C., Tan, Y. W. & Li, Y. F. Conducting polyaniline nanofiber networks prepared by the doping induction of camphor sulfonic acid. Journal of Applied Polymer Science 87, 1537-1540 (2003).
166. Kahol, P. K. & Pinto, N. J. Electron paramagnetic resonance investigations of electrospun polyaniline fibers. Solid State Communications 124, 195-197 (2002).
167. Huang, K. & Wan, M. X. Self-assembled polyaniline nanostructures with photoisomerization function. Chemistry of Materials 14, 3486-3492 (2002).
168. Ikegame, M., Tajima, K. & Aida, T. Template synthesis of polypyrrole nanofibers insulated within one-dimensional silicate channels: Hexagonal versus lamellar for recombination of polarons into bipolarons. Angewandte Chemie-International Edition 42, 2154-2157 (2003).
169. Duvail, J. L. et al. Physical properties of conducting polymer nanofibers. Synthetic Metals 135, 329-330 (2003).
170. MacDiarmid, A. G. et al. Electrostatically-generated nanofibers of electronic polymers. Synthetic Metals 119, 27-30 (2001).
171. Sailor, M. J. & Curtis, C. L. Conducting Polymer Connections for Molecular Devices. Advanced Materials 6, 688-692 (1994).
172. Zhang, F. L., Nyberg, T. & Inganas, O. Conducting polymer nanowires and nanodots made with soft lithography. Nano Letters 2, 1373-1377 (2002).
173. Duvail, J. L. et al. Transport and vibrational properties of poly(3,4-ethylenedioxythiophene) nanofibers. Synthetic Metals 131, 123-128 (2002).
174. Chen, S. H., Fan, Z. Y. & Carroll, D. L. Silver nanodisks: Synthesis, characterization, and self-assembly. Journal of Physical Chemistry B 106, 10777-10781 (2002).
175. Coleman, N. R. B. et al. Synthesis and characterization of dimensionally ordered semiconductor nanowires within mesoporous silica. Journal of the American Chemical Society 123, 7010-7016 (2001).
176. Flahaut, E., Agnoli, F., Sloan, J., O'Connor, C. & Green, M. L. H. CCVD synthesis and characterization of cobalt-encapsulated nanoparticles. Chemistry of Materials 14, 2553-2558 (2002).
177. Gao, S. M. et al. Mild benzene-thermal route to GaP nanorods and nanospheres. Inorganic Chemistry 41, 1850-1854 (2002).
178. He, R., Qian, X. F., Yin, J. & Zhu, Z. K. Preparation of polychrome silver nanoparticles in different solvents. Journal of Materials Chemistry 12, 3783-3786 (2002).
179. Hu, J. Q., Deng, B., Zhang, W. X., Tang, K. B. & Qian, Y. T. Synthesis and characterization of CdIn₂S₄ nanorods by converting CdS nanorods via the hydrothermal route. Inorganic Chemistry 40, 3130-3133 (2001).
180. Li, G. L., Wang, G. H. & Hong, J. M. Synthesis and characterization of rutile TiO₂ nanowhiskers. Journal of Materials Research 14, 3346-3354 (1999).
181. Li, L. S. & Alivisatos, A. P. Semiconductor nanorod liquid crystals and their assembly on a substrate. Advanced Materials 15, 408-+ (2003).
182. Li, W. J. et al. Hydrothermal synthesis of MoS₂ nanowires. Journal of Crystal Growth 250, 418-422 (2003).
183. Lifshitz, E. et al. Synthesis and characterization of PbSe quantum wires, multipods, quantum rods, and cubes. Nano Letters 3, 857-862 (2003).
184. Liu, Y. F. et al. Hydrothermal synthesis of square thin flake CdS by using surfactants and thiocarbohydrate. Materials Research Bulletin 36, 1231-1236 (2001).
185. Mayers, B. & Xia, Y. N. One-dimensional nanostructures of trigonal tellurium with various morphologies can be synthesized using a solution-phase approach. Journal of Materials Chemistry 12, 1875-1881 (2002).
186. Shao, M. W. et al. Microwave-templated synthesis of CdS nanotubes in aqueous solution at room temperature. New Journal of Chemistry 26, 1440-1442 (2002).
187. Shen, G. Z., Chen, D., Tang, K. B., Jiang, X. & Qian, Y. T. A rapid ethylenediamine-assisted polyol route to synthesize Sb₂E₃ (E=S, Se) nanowires. Journal of Crystal Growth 252, 350-354 (2003).
188. Wu, S. D., Zhu, Z. G., Zhang, Z. P. & Zhang, L. Preparation of the US semiconductor nanofibril by UV irradiation. Materials Science and Engineering B-Solid State Materials for Advanced Technology 90, 206-208 (2002).
189. Xu, J. & Li, Y. D. Formation of zinc sulfide nanorods and nanoparticles in ternary W/O microemulsions. Journal of Colloid and Interface Science 259, 275-281 (2003).
190. Yin, Y. D., Lu, Y., Sun, Y. G. & Xia, Y. N. Silver nanowires can be directly coated with amorphous silica to generate well-controlled coaxial nanocables of silver/silica. Nano Letters 2, 427-430 (2002).
191. Yu, S. H. et al. In situ fabrication and optical properties of a novel polystyrene/semiconductor nanocomposite embedded with CdS nanowires by a soft solution processing route. Langmuir 17, 1700-1707 (2001).
192. Zhou, H. C., Xu, J., Xu, S. & Li, Y. D. Synthesis and characterization of CaSO₄ nanorods (wires) in microemulsion system. Chinese Journal of Inorganic Chemistry 18, 815-818 (2002).
193. Zhou, S. M., Feng, Y. S. & Zhang, L. D. Sonochemical synthesis of large-scale single crystal CdS nanorods. Materials Letters 57, 2936-2939 (2003).
194. Zhu, J. J., Wang, H., Zhu, J. M. & Wang, J. A rapid synthesis route for the preparation of CdS nanoribbons by microwave irradiation. Materials Science and Engineering B-Solid State Materials for Advanced Technology 94, 136-140 (2002).
195. Yang, P. D. & Kim, F. Langmuir-Blodgett assembly of one-dimensional nanostructures. Chemphyschem 3, 503-+ (2002).
196. Reitzel, N. et al. Langmuir and Langmuir-Blodgett films of amphiphilic hexa-peri-hexabenzocoronene: New phase transitions and electronic properties controlled by pressure. Chemistry-a European Journal 7, 4894-4901 (2001).
197. Liu, J. F., Yang, K. Z. & Lu, Z. H. Controlled assembly of regular composite nanowire arrays and their multilayers using electropolymerized polymers as templates. Journal of the American Chemical Society 119, 11061-11065 (1997).
198. Wang, Z. L. & Pan, Z. W. Junctions and networks of SnO nanoribbons. Advanced Materials 14, 1029-+ (2002).
199. Li, D. & Xia, Y. N. Fabrication of titania nanofibers by electrospinning. Nano Letters 3, 555-560 (2003).
200. Theron, A., Zussman, E. & Yarin, A. L. Electrostatic field-assisted alignment of electrospun nanofibres. Nanotechnology 12, 384-390 (2001).
201. Dekker, C. Carbon nanotubes as molecular quantum wires. Physics Today 52, 22-28 (1999).
202. Snow, E. S., Novak, J. P., Campbell, P. M. & Park, D. Random networks of carbon nanotubes as an electronic material. Applied Physics Letters 82, 2145-2147 (2003).

What is claimed is:

1. A semiconductor device comprising:
a drain electrode;
a source electrode;
a gate electrode;
a semiconductor layer located between said drain electrode and said source electrode, said semiconductor layer providing an electrical connection between said drain electrode and said source electrode wherein said semiconductor layer comprises a network of molecular nanowires; and
a layer of electrically insulating material located between said gate electrode and said semiconductor layer.

2. A semiconductor device according to claim 1 wherein said network of molecular nanowires comprises nanowires having diameters of less than 500 nm and an aspect ratio of at least 10.

3. A semiconductor device according to claim 1 wherein said network of molecular nanowires comprises molecular nanowires selected from the group consisting of single element nanowires, Group III-V nanowire, Group II-VI nanowires, metal oxide nanowires, metal chalcogenide nanowires, ternary chalcogenide nanowires and conducting polymer nanowires.

4. A semiconductor device according to claim 3 wherein said network of molecular nanowires comprises one or more conducting polymer nanowires.

5. A semiconductor device according to claim 4 wherein said one or more conducting polymer nanowires consist essentially of polyaniline.

6. In a field effect transistor that includes a source electrode, which is electrically connected to a drain electrode by way of a semiconductor material, wherein the improvement comprises using a network of molecular nanowires as said semiconductor material.

7. The improvement in field effect transistors according to claim 6 wherein said network of molecular nanowires comprises nanowires having diameters of less than 500 nm and an aspect ratio of at least 10.

8. The improvement in field effect transistors according to claim 6 wherein said network of molecular nanowires comprises molecular nanowires selected from the group consisting of single element nanowires, Group III-V nanowire, Group II-VI nanowires, metal oxide nanowires, metal chalcogenide nanowires, ternary chalcogenide nanowires and conducting polymer nanowires.

9. The improvement in field effect transistors according to claim 8 wherein said network of molecular nanowires comprises one or more conducting polymer nanowires.

10. The improvement in field effect transistors according to claim 9 wherein said one or more conducting polymer nanowires consist essentially of polyaniline.

11. A method for making a semiconductor device comprising the steps of:
providing a drain electrode;
providing a source electrode;
providing a gate electrode;
providing a semiconductor layer located between said drain electrode and said source electrode such that an electrical connection between said drain electrode and said source electrode is formed wherein said semiconductor layer comprises a network of molecular nanowires; and
providing a layer of electrically insulating material located between said gate electrode and said semiconductor layer.

12. A method for making a semiconductor device according to claim 11 wherein said network of molecular nanowires comprises nanowires having diameters of less than 500 nm and an aspect ration of at least 10.

13. A method for making a semiconductor device according to claim 11 wherein said network of molecular nanowires comprises molecular nanowires selected from the group consisting of single element nanowires, Group III-V nanowire, Group II-VI nanowires, metal oxide nanowires, metal chalcogenide nanowires, ternary chalcogenide nanowires and conducting polymer nanowires.

14. A method for making a semiconductor device according to claim 13 wherein said network of molecular nanowires comprises one or more conducting polymer nanowires.

15. A method for making a semiconductor device according to claim 14 wherein said one or more conducting polymer nanowires consist essentially of polyaniline

16. A method for making a semiconductor device according to claim 11 wherein said step of providing said semiconductor layer comprises forming said network of molecular nanowires on said layer of electrically insulating material by solution casting, a Langmuir-Blodgett technique, chemical vapor deposition or electrospinning.

17. A method for controlling the flow of electrical current between a source electrode and a drain electrode in a field effect transistor, said method comprising the steps of:
1) providing a field effect transistor comprising:
a drain electrode;
a source electrode;
a gate electrode;
a semiconductor layer located between said drain electrode and said source electrode, said semiconductor layer providing an electrical connection between said drain electrode and said source electrode wherein said semiconductor layer comprises a network of molecular nanowires;
a layer of electrically insulating material located between said gate electrode and said semiconductor layer; and
2) applying an electrical potential to said gate electrode to thereby provide control of the flow electrical current between said source electrode and said drain electrode.

18. A method for controlling the flow of electrical current between a source electrode and a drain electrode in a field effect transistor according to claim 17 wherein said network of molecular nanowires comprises nanowires having diameters of less than 500 nm and an aspect ratio of at least 10.

19. A method for controlling the flow of electrical current between a source electrode and a drain electrode in a field effect transistor according to claim 17 wherein said network of molecular nanowires comprises molecular nanowires selected from the group consisting of single element nanowires, Group III-V nanowire, Group II-VI nanowires, metal oxide nanowires, metal chalcogenide nanowires, ternary chalcogenide nanowires and conducting polymer nanowires.

20. A method for controlling the flow of electrical current between a source electrode and a drain electrode in a field effect transistor according to claim 19 wherein said network of molecular nanowires comprises one or more conducting polymer nanowires.

21. A method for controlling the flow of electrical current between a source electrode and a drain electrode in a field effect transistor according to claim 20 wherein said one or more conducting polymer nanowires consist essentially of polyaniline.
